(19) United States
(12) Patent Application Publication
(10) Pub. No.: US 2026/0304980 A1
(43) Pub. Date: Oct. 1, 2026

(54) IMAGE SENSOR MODULE

(71) Applicant: VisEra Technologies Company Limited, Hsin-Chu City (TW)

(72) Inventors: Chia-Ning HSU, Hsin-Chu City (TW); Bo-Lun CHEN, Hsin-Chu City (TW); Huang-Jen CHEN, Hsin-Chu City (TW); Han-Sheng CHEN, Hsin-Chu City (TW)

(21) Appl. No.: 19/092,399

(22) Filed: Mar. 27, 2025

(51) Int. Cl. H10F 39/00; H10F 39/18

(52) U.S. Cl. CPC H10F 39/8057; H10F 39/182

(57) ABSTRACT

The image sensor module includes a substrate, a plurality of optical assemblies, at least two shielding members, a filling member, and a color filter. The substrate includes a first area and a second area. The optical assemblies are disposed over the substrate in the first area. The shielding members are disposed over the substrate in the second area, and the shielding members are separated from each other to form a trench therebetween. The filling member is disposed over the shielding member in the second area and filled into the trench. The filling member has a pattern formed by a plurality of pattern units, and the pattern is adjacent to the first area. The color filter is disposed over the filling member in the second area.

### BACKGROUND OF THE INVENTION

### Field of the Invention

The application relates in general to an image sensor module, and in particular, to an image sensor module that has a filling member with a pattern.

### Description of the Related Art

Image sensors, such as complementary metal-oxide-semiconductor (CMOS) image sensors (also known as CIS), are widely used in various image-capturing apparatuses such as digital still-image cameras, digital video cameras, and the like. The light-sensing units in an image sensor may detect ambient color changes, and signal electric charges may be generated depending on the amount of light received by the light-sensing units. In addition, the signal electric charges generated by the light-sensing units may be transmitted and amplified, whereby an image signal is obtained.

However, current image sensors usually suffer from issues of sensing area striation and discoloration, such as stripe defects and frame mura. Therefore, how to address the aforementioned problem has become an important issue.

### BRIEF SUMMARY OF INVENTION

To address the deficiencies of conventional products, an embodiment of the invention provides an image sensor module. The image sensor module includes a substrate, a plurality of optical assemblies, at least two shielding members, a filling member, and a color filter. The substrate includes a first area and a second area. The optical assemblies are disposed over the substrate in the first area. The shielding members are disposed over the substrate in the second area, and the shielding members are separated from each other to form a trench therebetween. The filling member is disposed over the shielding member in the second area and filled into the trench. The filling member has a pattern formed by a plurality of pattern units, and the pattern is adjacent to the first area. The color filter is disposed over the filling member in the second area.

In some embodiments, the image sensor module further includes a metal pad and an additional filling member. The substrate has a depression portion below the trench. The additional filling member is filled in the depression portion, and the metal pad is disposed below the depression portion.

In some embodiments, the color filter includes a first portion and a second portion. The first portion is above the shielding members, and the second portion is above the trench. A first distance is formed between an upper surface of the first portion and an interface between the first portion and the filling member, a second distance is formed between an upper surface of the second portion and an interface between the second portion and the filling member, and the first distance is different from the second distance.

In some embodiments, a value of the first distance minus the second distance is within a range of −0.6 mm to 0.6 mm.

In some embodiments, a third distance is formed between the interface between first portion and the filling member and an upper surface of each of the shielding members, and the third distance is within a range of 0 to 0.6 mm.

In some embodiments, the distance between the trench and the pattern is within a range of 0 to 100 mm.

In some embodiments, the pattern units are holes, and each hole has a polygonal structure.

In some embodiments, the holes are arranged in a matrix, the side length of each hole is within a range of 0 to 100 mm, the internal angle of each hole is less than 180 degrees, and the distance between the centers of adjacent holes is within a range of 0 to 100 mm.

In some embodiments, the pattern includes a plurality of holes, and each hole has a circular structure.

In some embodiments, the holes are arranged in a matrix, the diameter of each hole is within a range of 0 to 100 mm, and the distance between the centers of adjacent holes is within a range of 0 to 100 mm.

In some embodiments, the pattern units are pillars, and the pillars are arranged in a checkerboard manner.

In some embodiments, each pillar has a cuboid structure. The length and the width of each pillar are within a range of 1 μm and 100 mm. The height of each pillar is within a range of 0 to 0.6 mm. The distance between the centers of adjacent pillars in the same row is within a range of 0 and 100 mm.

In some embodiments, each pillar has a truncated pyramid structure. The length and the width of the top surface of each pillar is within a range of 1 μm and 100 mm. The height of each pillar is within a range of 0 to 0.6 mm. The angle between the side surface and the bottom surface of each pillar is within a range of 0° to 90°. The distance between the centers of adjacent pillars in the same row is within a range of 0 and 100 mm.

In some embodiments, the pattern units are pillars, and the pillars are arranged in a matrix.

In some embodiments, the pillars have different dimensions.

In some embodiments, the filling member comprises a first layer and a second layer. The second layer is disposed over the first layer. The refractive index of the first layer is different than the refractive index of the second layer.

In some embodiments, each of the optical assemblies comprises a light shielding structure, a first grid structure, and a second grid structure. The first grid structure covers the light shielding structure, and the second grid structure is connected the first grid structure. The material of the first layer is the same as the material of the first grid structure. The material of the second layer is the same as the material of the second grid structure.

In some embodiments, the first layer is made of metal or organic material, and the second layer is made of metal or organic material.

In some embodiments, each of the optical assemblies comprises a light shielding structure and a first grid structure. The first grid structure covers the light shielding structure. The material of the first grid structure is the same as the material of the filling member.

In some embodiments, the filling member is an additional color filter.

### BRIEF DESCRIPTION OF DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1A is a schematic diagram of an image sensor module according to an embodiment of the invention;

FIG. 1B is a schematic diagram of the pattern adjacent to the first area according to an embodiment of the invention;

FIG. 2A is a schematic diagram of the pattern units in the pattern of the filling member according to some embodiments of the invention;

FIG. 2B is a schematic diagram of the pattern units in the pattern of the filling member according to some embodiments of the invention;

FIG. 2C is a schematic diagram of the pattern units in the pattern of the filling member according to some embodiments of the invention;

FIG. 3A is a schematic diagram of the pattern adjacent to the first area according to another embodiment of the invention;

FIG. 3B is a schematic diagram of the pattern unit in the pattern of the filling member according to some embodiments of the invention;

FIG. 3C is a schematic diagram of the pattern unit in the pattern of the filling member according to some embodiments of the invention;

FIG. 4A is a schematic diagram of the pattern units in the pattern of the filling member according to some embodiments of the invention;

FIG. 4B is a schematic diagram of the pattern units in the pattern of the filling member according to some embodiments of the invention;

FIG. 4C is a schematic diagram of the pattern units in the pattern of the filling member according to some embodiments of the invention;

FIG. 4D is a schematic diagram of the pattern units in the pattern of the filling member according to some embodiments of the invention;

FIG. 4E is a schematic diagram of the pattern units in the pattern of the filling member according to some embodiments of the invention;

FIG. 5A is a schematic diagram of the optical assembly disposed in the first area according to some embodiments of the invention;

FIG. 5B is a schematic diagram of the optical assembly disposed in the first area according to some embodiments of the invention;

FIG. 5C is a schematic diagram of the optical assembly disposed in the first area according to some embodiments of the invention; and

FIG. 6 is a schematic diagram of an image sensor module according to another embodiment of the invention.

### DETAILED DESCRIPTION OF INVENTION

The making and using of the embodiments of the image sensor module are discussed in detail below. It should be appreciated, however, that the embodiments provide many applicable inventive concepts that can be embodied in a wide variety of specific contexts. The specific embodiments discussed are merely illustrative of specific ways to make and use the embodiments, and do not limit the scope of the disclosure.

Unless defined otherwise, all technical and scientific terms used herein have the same meaning as commonly understood by one of ordinary skill in the art to which this invention belongs. It should be appreciated that each term, which is defined in a commonly used dictionary, should be interpreted as having a meaning conforming to the relative skills and the background or the context of the present disclosure, and should not be interpreted in an idealized or overly formal manner unless defined otherwise.

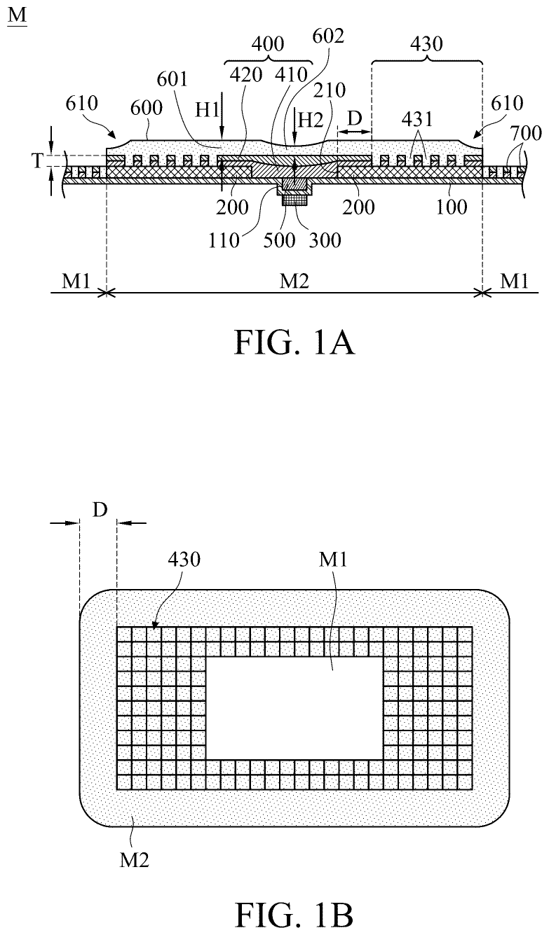

FIG. 1A is a schematic diagram of an image sensor module M according to an embodiment of the invention. It should be noted that, FIG. 1A merely shows a part of the image sensor module M, and the image sensor module M may contain a plurality of duplicated parts shown in FIG. 1A. For example, the image sensor module M can be a CMOS (complementary metal-oxide-semiconductor) image sensor, but it is not limited thereto.

As shown in FIG. 1A and FIG. 1B, the image sensor module M can primarily include a substrate 100, at least two light shielding members 200, a metal pad 300, a filling member 400, an additional filling member 500, a color filter 600, and a plurality of optical assemblies 700.

The substrate 100 includes a first area M1 and a second area M2, and the second area M2 surrounds the first area M1. The light shielding members 200 are disposed above the substrate 100 in the second area M2, and are separated from each other so that a trench 210 is formed between them. In this embodiment, the substrate 100 has a depression portion 110 below the trench 210.

The metal pad 300 is disposed below the depression portion 110 and is in contact with the substrate 100. The additional filling member 500 is filled in the depression portion 110. For example, the additional filling member 500 can include photoresist material.

The filling member 400 is disposed over the shielding members 200 in the second area M2 and filled into the trench 210. In other words, the filling member 400 covers at least a portion of the light shielding members 200 and the additional filling member 500.

In this embodiment, the filling member 400 includes a first layer 410 and a second layer 420 disposed over the first layer 410.. The first layer 410 and the second layer 420 can be made of the metal or organic material, and the refractive index of the first layer 410 can be the same as or different from the refractive index of the second layer 420. In some embodiments, the first layer 410 and the second layer 420 can be integrally formed as one piece. In some embodiments, the filling member 400 can include more than two layers.

As shown in FIG. 1A and FIG. 1B, specifically, the filling member 400 includes a pattern 430 that is adjacent to the first area M1. The pattern 430 can be formed by a plurality of patten units 431. In this embodiment, the pattern units 431 are holes, and are formed by lithograph and etching. The distance D between the trench 210 and the pattern 430 can be ranged from 0 to 100 mm (0≤D≤100 mm).

The color filter 600 is disposed over the filling member 400 in the second area M2 and filled into the pattern units 431 of the pattern 430. In detail, the color filter 600 can includes a first portion 601 and a second portion 602, the first portion 601 is above the shielding members 200, and the second portion 602 is above the trench 210. A first distance H1 is formed between the upper surface of the first portion 601 and the interface between the first portion 601 and the filling member 400, and a second distance H2 is formed between the upper surface of the second portion 602 and the interface between the second portion 602 and the filling member 400. The value of the first distance H1 minus the second distance H2 is within a range of −0.6 mm to 0.6 mm (−0.6 mm≤H1−H2≤0.6 mm). Moreover, a third distance T is formed between the interface between the first portion 601 and the filling member 400 and the upper surface of each of the shielding members 200, and the third distance T is within a range of 0 to 0.6 mm (0≤T≤0.6 mm).

Because the filling member 400 includes a pattern 430 that is adjacent to the first area M1, the coating process for the color filter 600 in the second area M2 can be more uniform, so that there is no striation and frame mura for macro discolor defect after the lithography process.

Moreover, in this embodiment, the color filter 600 can include a tapered portion 610 that is gradually increased from the border between the first area M1 and the second area M2, so as to further reduce the issue of the striation and frame mura.

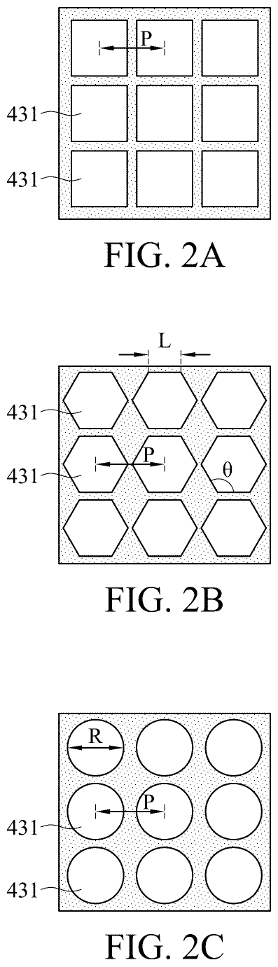

Referring to FIG. 2A to FIG. 2C, the holes (the pattern units 431) of the pattern 430 on the filling member 400 can be arranged in a matrix, and the shape of each hole can include a polygonal structure or a circular structure.

In FIG. 2A, the shape of each hole includes a square structure, and the distance P between the centers of adjacent holes is within a range of 0 to 100 mm (0≤P≤100 mm). In FIG. 2B, the shape of each hole includes a hexagonal structure, the side length L of each hole is within a range of 0 to 100 mm (0≤L≤100 mm), the internal angle θ of each hole is less than 180 degrees (θ<180 degrees), and the distance P between the centers of adjacent holes is within a range of 0 to 100 mm (0≤P≤100 mm). In FIG. 2C, the shape of each hole includes a circular structure, the diameter R of each hole is within a range of 0 to 100 mm (0≤R≤100 mm), and the distance P between the centers of adjacent holes is within a range of 0 to 100 mm (0≤P≤100 mm). In some embodiments, the shape of each hole includes a triangular structure, a quadrangular structure, or a pentagonal structure, but it is not limited thereto.

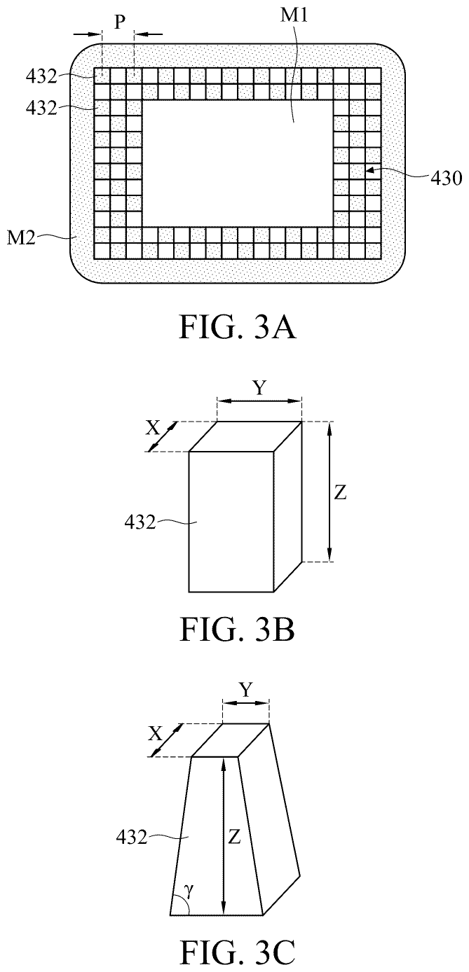

Referring to FIG. 3A, in some embodiments, the pattern 430 can be formed by a plurality of pattern units 432. The pattern units 432 are pillars and are arranged in a checkerboard manner. The distance P between the centers of adjacent pillars in the same row may be within a range of 0 and 100 mm (0<P<100 mm). The pillars of the pattern 430 can be any suitable shape. For example, as shown in FIG. 3B, each pillar can have a cuboid structure. The length X of each pillar is within a range of 1 μm and 100 mm (1 μm<X<100 mm), the width Y of each pillar is within a range of 1 μm and 100 mm (1 μm<Y<100 mm), and the height Z of each pillar is within a range of 0 to 0.6 mm (0≤Z≤0.6 mm).

As shown in FIG. 3C, in some embodiments, each pillar of the pattern 430 can hav a truncated pyramid structure. The length X of the top surface of each pillar is within a range of 1 μm and 100 mm (1 μm<X<100 mm). The width Y of each pillar is within a range of 1 μm and 100 mm (1 μm<Y<100 mm). The height Z of each pillar is within a range of 0 to 0.6 mm (0≤Z≤0.6 mm). The angle γ between the side surface and the bottom surface of each pillar is within a range of 0° to 90° (0°<γ<90°).

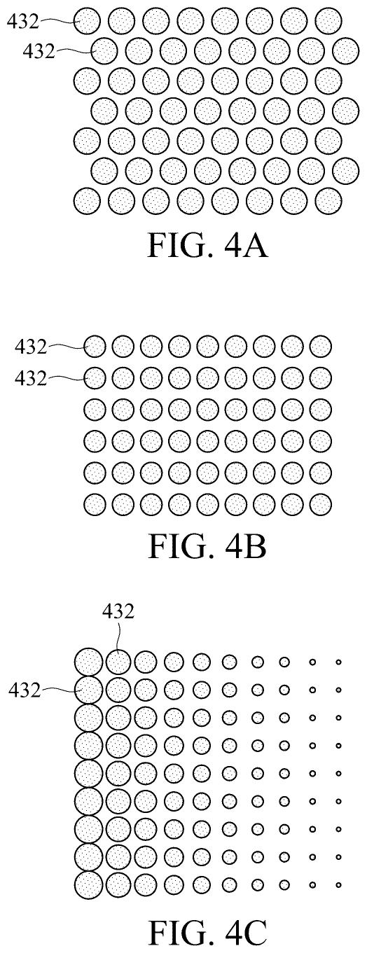

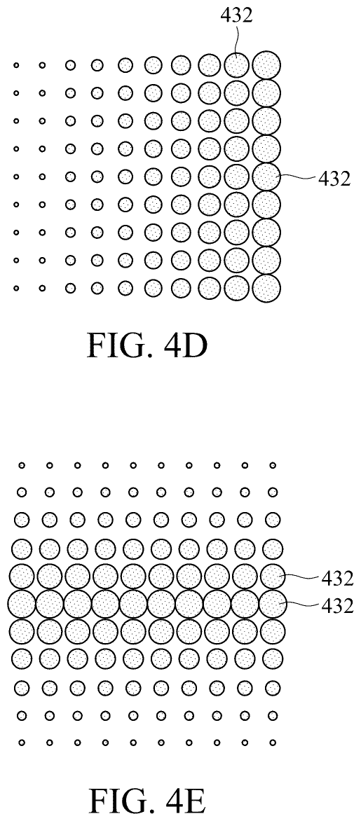

Referring to FIG. 4A to FIG. 4E, the pillars of the pattern 430 can be arranged in a checkerboard manner (FIG. 4A) or in a matrix (FIGS. 4B-4E). The dimensions of each pillar in the pattern 430 can be the same or different, and the gap between adjacent pillars can be equidistant or unequal. For example, the pillars have the same dimensions in the embodiments shown in FIG. 4A and FIG. 4B, and the pillars have the different dimensions in the embodiments shown in FIG. 4C to FIG. 4E. In FIG. 4C, the dimensions of the pillars are gradually increased from the border between the first area M1 and the second area M2. In FIG. 4D, the dimensions of the pillars are gradually decreased from the border between the first area M1 and the second area M2. In FIG. 4E, the dimensions of the pillars in the central row are largest, and in the row farther away from the central row, the smaller the dimensions of the pillars.

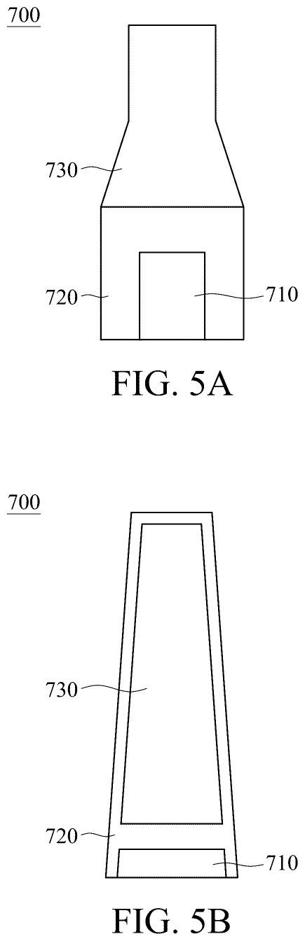

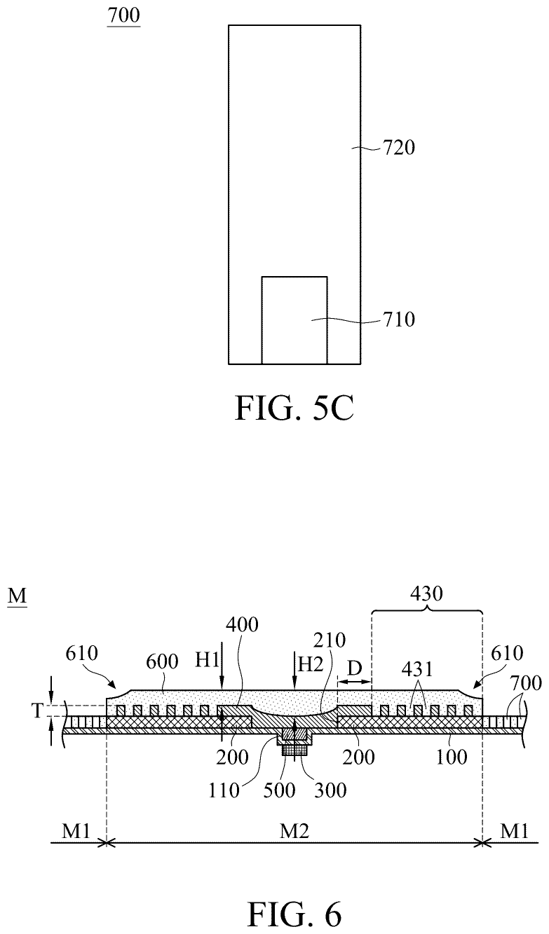

Referring to FIG. 1 and FIG. 5A, the optical assemblies 700 are disposed over the substrate 100 in the first area M1, so that the first area M1 can be referred as the sensing area. Each of the optical assemblies 700 can include a light shielding structure 710, a first grid structure 720, and a second grid structure 730. The first grid structure 720 can cover the light shielding structure 710, and the second grid structure 730 can be disposed over and connected to the first grid structure 720. The light shielding structure 710 can include metal, metal nitride, and/or metal oxide, and the first grid structure 720 and the second grid structure 730 can include metal and/or organic oxide material.

The refractive index of the first grid structure 720 can be different from the refractive index of the second grid structure 730. The material of the first grid structure 720 can be the same as that of the first layer 410 of the filling member 400, and the material of the second grid structure 730 can be the same as that of the second layer 420 of the filling member 400. Therefore, the first grid structure 720 and the first layer 410 can be formed in the same process, the second grid structure 730 and the second layer 420 can be formed in the same process, and the production efficiency can be enhanced.

As shown in FIG. 5B, in another embodiment, each of the optical assemblies 700 can include a light shielding structure 710, a first grid structure 720, and a second grid structure 730. The first grid structure 720 is disposed over the light shielding structure 710, the second grid structure 730 is connected to the first grid structure 720, and the first grid structure 720 surrounds the light shielding structure 710 and the second grid structure 730. The light shielding structure 710 can include metal, metal nitride, and/or metal oxide, and the first grid structure 720 and the second grid structure 730 can include metal and/or organic oxide material. Similarly, in this embodiment, the refractive index of the first grid structure 720 can be different from the refractive index of the second grid structure 730, the material of the first grid structure 720 can be the same as that of the first layer 410 of the filling member 400, and the material of the second grid structure 730 can be the same as that of the second layer 420 of the filling member 400. Therefore, the first grid structure 720 and the first layer 410 can be formed in the same process, the second grid structure 730 and the second layer 420 can be formed in the same process, and the production efficiency can be enhanced.

As shown in FIG. 5C, in another embodiment, each of the optical assemblies 700 can include a light shielding structure 710 and a first grid structure 720, and the first grid structure 720 is disposed over the light shielding structure 710. The light shielding structure 710 can include metal, metal nitride, and/or metal oxide, and the first grid structure 720 can include metal and/or organic oxide material. In this embodiment, the first layer 410 and the second layer 420 of the filling member 400 can be integrally formed as one piece (i.e. the filling member 400 has a single layer). The material of the first grid structure 720 can be the same as that of the filling member 400, so that they can be formed in the same process, and the production efficiency can be enhanced.

It should be noted that, in some embodiments, the light shielding structure 710 in FIG. 5A to FIG. 5C can be also omitted.

Referring to FIG. 6, in another embodiment, the image sensor module M includes substrate 100, at least two light shielding members 200, a metal pad 300, a filling member 400, an additional filling member 500, a color filter 600, and a plurality of optical assemblies 700, wherein the arrangements and the structures of the substrate 100, the light shielding members 200, the metal pad 300, the additional filling member 500, the color filter 600, and the optical assemblies 700 are the same as that in the aforementioned embodiments, so that the features thereof are not repeated in the interest of brevity.

In this embodiment, the filling member 400 is also a color filter (an additional color filter), and the pattern 430 on the filling member 400 can be formed only by lithography. Therefore, the processes of manufacturing the image sensor module M can be simplified, and the manufacturing time can be reduced.

The features between the aforementioned embodiments can be used or combined as long as they do not violate or conflict the spirit of the present application

In summary, an embodiment of the disclosure provides an image sensor module. The image sensor module includes a substrate, a plurality of optical assemblies, at least two shielding members, a filling member, and a color filter. The substrate includes a first area and a second area. The optical assemblies are disposed over the substrate in the first area. The shielding members are disposed over the substrate in the second area, and the shielding members are separated from each other to form a trench therebetween. The filling member is disposed over the shielding member in the second area and filled into the trench. The filling member has a pattern formed by a plurality of pattern units, and the pattern is adjacent to the first area. The color filter is disposed over the filling member in the second area.

Although some embodiments of the present disclosure and their advantages have been described in detail, it should be understood that various changes, substitutions and alterations can be made herein without departing from the spirit and scope of the disclosure as defined by the appended claims. For example, it will be readily understood by those skilled in the art that many of the features, functions, processes, and materials described herein may be varied while remaining within the scope of the present disclosure. Moreover, the scope of the present application is not intended to be limited to the particular embodiments of the process, machine, manufacture, compositions of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps. Moreover, the scope of the appended claims should be accorded the broadest interpretation so as to encompass all such modifications and similar arrangements.

While the invention has been described by way of example and in terms of preferred embodiment, it should be understood that the invention is not limited thereto. On the contrary, it is intended to cover various modifications and similar arrangements (as would be apparent to those skilled in the art). Therefore, the scope of the appended claims should be accorded the broadest interpretation to encompass all such modifications and similar arrangements.

What is claimed is:

1. An image sensor module, comprising:
a substrate, comprising a first area and a second area;
a plurality of optical assemblies, disposed over the substrate in the first area;
at least two shielding members, disposed over the substrate in the second area, wherein the shielding members are separated from each other to form a trench therebetween;
a filling member, disposed over the shielding members in the second area and filled into the trench, wherein the filling member has a pattern formed by a plurality of pattern units, and the pattern is adjacent to the first area; and
a color filter, disposed over the filling member in the second area.

2. The image sensor module as claimed in claim 1, further comprising an additional filling member and a metal pad, wherein the substrate has a depression portion below the trench, the additional filling member is filled in the depression portion, and the metal pad is disposed below the depression portion.

3. The image sensor module as claimed in claim 1, wherein the color filter comprises a first portion and a second portion, the first portion is above the shielding members, and the second portion is above the trench, wherein a first distance is formed between an upper surface of the first portion and an interface between the first portion and the filling member, a second distance is formed between an upper surface of the second portion and an interface between the second portion and the filling member, and the first distance is different from the second distance.

4. The image sensor module as claimed in claim 3, wherein a value of the first distance minus the second distance is within a range of −0.6 mm to 0.6 mm.

5. The image sensor module as claimed in claim 3, wherein a third distance is formed between the interface between the first portion and the filling member and an upper surface of each of the shielding members, and the third distance is within a range of 0 to 0.6 mm.

6. The image sensor module as claimed in claim 1, wherein a distance between the trench and the pattern is within a range of 0 to 100 mm.

7. The image sensor module as claimed in claim 1, wherein the pattern units are holes, and each hole has a polygonal structure.

8. The image sensor module as claimed in claim 7, wherein the holes are arranged in a matrix, a side length of each hole is within a range of 0 to 100 mm, an internal angle of each hole is less than 180 degrees, and a distance between centers of adjacent holes is within a range of 0 to 100 mm.

9. The image sensor module as claimed in claim 1, wherein the pattern units are holes, and each hole has a circular structure.

10. The image sensor module as claimed in claim 9, wherein the holes are arranged in a matrix, a diameter of each hole is within a range of 0 to 100 mm, and a distance between centers of adjacent holes is within a range of 0 to 100 mm.

11. The image sensor module as claimed in claim 1, wherein the pattern units are pillars, and the pillars are arranged in a checkerboard manner.

12. The image sensor module as claimed in claim 11, wherein each pillar has a cuboid structure, a length and a width of each pillar are within a range of 1 μm and 100 mm, the height of each pillar is within a range of 0 to 0.6 mm, and a distance between centers of adjacent pillars in the same row is within a range of 0 and 100 mm.

13. The image sensor module as claimed in claim 11, wherein each pillar has a truncated pyramid structure, a length and a width of a top surface of each pillar are within a range of 1 μm and 100 mm, the height of each pillar is within a range of 0 to 0.6 mm, an angle between a side surface and a bottom surface of each pillar is within a range of 0° to 90°, and a distance between centers of adjacent pillars in the same row is within a range of 0 and 100 mm.

14. The image sensor module as claimed in claim 1, wherein the pattern units are pillars, and the pillars are arranged in a matrix.

15. The image sensor module as claimed in claim 14, wherein the pillars have different dimensions.

16. The image sensor module as claimed in claim 1, wherein the filling member comprises a first layer and a second layer, the second layer is disposed over the first layer, and a refractive index of the first layer is different from a refractive index of the second layer.

17. The image sensor module as claimed in claim 16, wherein each of the optical assemblies comprises a light shielding structure, a first grid structure, and a second grid structure, the first grid structure covers the light shielding structure, and the second grid structure is connected the first grid structure, wherein a material of the first layer is the same as a material of the first grid structure, and a material of the second layer is the same as a material of the second grid structure.

18. The image sensor module as claimed in claim 16, wherein the first layer is made of metal or organic material, and the second layer is made of metal or organic material.

19. The image sensor module as claimed in claim 1, wherein each of the optical assemblies comprises a light shielding structure and a first grid structure, the first grid structure covers the light shielding structure, and a material of the first grid structure is the same as a material of the filling member.

20. The image sensor module as claimed in claim 1, wherein the filling member is an additional color filter.
